(19) United States
(12) Patent Application Publication
(10) Pub. No.: US 2012/0012182 A1
(43) Pub. Date: Jan. 19, 2012

(54) PHOTOELECTRIC CONVERSION SEMICONDUCTOR LAYER, MANUFACTURING METHOD THEREOF, PHOTOELECTRIC CONVERSION DEVICE, AND SOLAR CELL

(75) Inventors: Tadanobu Satou, Ashigarakami-gun (JP); Makoto Kikuchi, Ashigarakami-gun (JP)

(73) Assignee: FUJIFILM CORPORATION, Minato-ku, Tokyo (JP)

(21) Appl. No.: 13/260,195

(22) PCT Filed: Mar. 19, 2010
(86) PCT No.: PCT/JP2010/055477

§ 371 Date: Sep. 23, 2011

(30) Foreign Application Priority Data
Mar. 25, 2009 (JP) 2009-073538

(51) Int. Cl. H01L 31/0264; H01L 31/18

(52) U.S. Cl. 136/262; 136/252; 438/57; 257/E31.119

(57) ABSTRACT

A photoelectric conversion semiconductor layer having high photoelectric conversion efficiency is provided at a low cost. Photoelectric conversion semiconductor layer is a layer that generates a current by absorbing light and is formed of a particle layer in which a plurality of plate-like particles is disposed only in a plane direction or a sintered body thereof, or a particle layer in which a plurality of plate-like particles is disposed in a plane direction and a thickness direction or a sintered body thereof.

### TECHNICAL FIELD

The present invention relates to a photoelectric conversion semiconductor layer, a manufacturing method thereof, a photoelectric conversion device using the same, and a solar cell.

### BACKGROUND ART

Photoelectric conversion devices having a stacked structure of a lower electrode (rear electrode), a photoelectric conversion semiconductor layer that generates a current by absorbing light, and an upper electrode are used in various applications, such as solar cells and the like. Most of the conventional solar cells are Si-based cells using bulk monocrystalline Si, polycrystalline Si, or thin film amorphous Si. Recently, however, research and development of compound semiconductor-based solar cells that do not depend on Si has been carried out. Two types of compound semiconductor-based solar cells are known, one of which is a bulk system, such as GaAs system and the like, and the other of which is a thin film system, such as CIS (Cu-In-Se) system formed of a group Ib element, a group IIIb element, and a group VIb element, CIGS (Cu-In-Ga-Se), or the like. The CIS system or CIGS system has a high light absorption rate and a high energy conversion efficiency value is reported.

As for methods of manufacturing CIGS layers, three-stage approach, selenidation method, and the like are known. These methods, however, employ vacuum film forming, requiring a high manufacturing cost and a large equipment investment. Consequently, a method in which particles containing Cu, In, Ga, and Se are coated and sintered is proposed as a non-vacuum method capable of manufacturing CIGS layers at a low cost.

“Nanoparticle derived Cu(In,Ga)Se₂ absorber layer for thin film solar cells”, S. Ahn et al., Colloids and Surface A: Physicochemical and Engineering Aspects, Vols. 313-314, pp. 171-174, 2008 (Non-patent Document 1), and “Effects of heat treatments on the properties of Cu(In,Ga)Se₂ nanoparticles”, S. Ahn et al., Solar Energy Materials and Solar Cells, Vol. 91, Issue 19, pp. 1836-1841, 2007 (Non-patent Document 2) propose a method in which spherical particles are coated on a substrate and sintered at a high temperature around 500° C. to crystallize the particles. These documents discuss reduction of heating time by rapid thermal process (RTP). A method in which one or more types of spherical oxide or alloy particles containing Cu, In, and Ga are coated on a substrate and heat treated at a high temperature around 500° C. in the presence of Se gas to selenide and crystallize the particles is proposed in U.S. Patent Application Publication No. 20050183768, Non-patent Document 2, and “CIS and CIGS layers from selenized nanoparticle precursors”, M. Kaelin et al., Thin Solid Films. Vols. 431-432, pp. 58-62, 2003 (Non-patent Document 3).

Each of the processes described above essentially requires a high temperature heat treatment process at around 500° C. and equipment for the high temperature heat treatment process is expensive, resulting in a heavy cost burden. Further, when continuous processing (roll-to-roll process) using a continuous strip-like flexible substrate is considered, even the RTP described in Non-patent Documents 1 and 2 requires at least 5 minutes for heat treatment. The heat treatment time of about 5 minutes is very long in comparison with a typical conveyance speed of roll-to-roll process of semiconductor devices and the length of the sintering furnace is unrealistically long. Therefore, it is preferable that CIGS layers are formed at a temperature as low as possible.

A method in which spherical CIGS particles are coated on a substrate and thereafter a high temperature heat treatment process is not implemented is proposed in “Monograin layer solar cells”, M. Altosaar et al., Thin Solid Films, Vols. 431-432, pp. 466-469, 2003 (Non-patent Document 4), “Further developments in CIS monograin layer solar cells technology”, M. Altosaar et al., Solar Energy Materials and Solar Cells, Vol. 87, Issues 1-4, pp. 25-32, 2005 (Non-patent Document 5), and “In-situ X-ray diffraction study of the initial dealloying of Cu₃Au (001) and Cu_{0.83}Pd_{0.17} (001)” F. U. Renner et al., Thin Solid Films, Vol. 515, Issue 14, pp. 5574-5580, 2007 (Non-patent Document 6). In such a method, the particle shape remains as it is because the method does not include a sintering process. In Non-patent Documents 4 to 6, a CIGS layer of single particle layer in which a plurality of spherical particles is disposed only in a plane direction.

The CIGS layer described in Non-patent Documents 4 to 6 is a particle layer of spherical particles, having a smaller contact area between the CIGS layer and an electrode, so that it is difficult to realize a photoelectric conversion efficiency which is comparable to that of a CIGS layer formed by vacuum film forming. For example, Non-patent Document 6 reports a conversion efficiency of 9.5% when non-light receiving areas such as the electrode are excluded. This is equivalent to 5.7% when converted to normal conversion efficiency. The value of 5.7% is less than half of that of the photoelectric conversion efficiency of the CIGS layer formed through vacuum film forming, proving that it is an impractical level.

“Synthesis of Colloidal CuGaSe₂, CuInSe₂, and Cu(InGa)Se₂ Nanoparticles”, J. Tang et al., Chem. Mater., Vol. 20, pp. 6906-6910, 2008 (Non-patent Document 7) describes a method of synthesizing plate-like CIGS particles. It reports only the particle synthesis and describes neither the utilization of the particles as a material of a photoelectric conversion layer nor a specific method of forming a photoelectric conversion layer.

The present invention has been developed in view of the circumstances described above, and it is an object of the present invention to provide a photoelectric conversion semiconductor layer that can be manufactured at a lower cost than that manufactured by vacuum film forming and has a higher photoelectric conversion efficiency than that described in Non-patent documents 4 to 6, and a method of manufacturing the layer.

That is, it is an object of the present invention to provide a photoelectric conversion semiconductor layer which can be manufactured at a lower cost than that formed by vacuum film forming without requiring high temperature processing exceeding 250° C. as essential processing and has a higher photoelectric conversion efficiency than that described in Non-patent Documents 4 to 6, and a method of manufacturing the layer.

### DISCLOSURE OF INVENTION

A photoelectric conversion semiconductor layer of the present invention is a semiconductor layer that generates a current by absorbing light, including a particle layer in which a plurality of plate-like particles is disposed only in a plate direction or a sintered body thereof, or a particle layer in which a plurality of plate-like particles is disposed in a plane direction and a thickness direction or a sintered body thereof.

A first photoelectric conversion semiconductor layer manufacturing method of the present invention is a method of manufacturing the photoelectric conversion semiconductor layer of the present invention described above, including the step of coating a coating material, which includes the .plurality of plate-like particles or the plurality of plate-like particles and a dispersion medium, on a substrate.

A second photoelectric conversion semiconductor layer manufacturing method of the present invention is a method of manufacturing the photoelectric conversion semiconductor layer of the present invention described above, the method including the steps of:

coating a coating material, which includes the plurality of plate-like particles and a dispersion medium, on a substrate; and

removing the dispersion medium.

Preferably, the step of removing the dispersion medium is a step performed at a temperature not higher than 250.

A photoelectric conversion device of the present invention is a device, including the photoelectric conversion semiconductor layer of the present invention and electrodes for extracting a current generated in the photoelectric conversion semiconductor layer. A preferred embodiment of the photoelectric conversion device of the present invention is an embodiment in which the photoelectric conversion semiconductor layer and the electrodes are formed on a flexible substrate.

Preferably, the flexible substrate is an anodized Al-based metal substrate having an anodized film on at least one surface side thereof .

A solar cell of the present invention is a solar cell, including the photoelectric conversion device of the present invention described above.

According to the present invention, a photoelectric conversion semiconductor layer that can be manufactured at a lower cost than that manufactured by vacuum film forming and has a higher photoelectric conversion efficiency than that described in Non-patent Documents 4 to 6 and a method of manufacturing the layer may be provided. According to the present invention a photoelectric conversion semiconductor layer which can be manufactured at a lower cost than that manufactured by vacuum film forming without requiring high temperature processing exceeding 250° C. and has a higher photoelectric conversion efficiency than that described in Non-patent Documents 4 to 6 and a method of manufacturing the layer may be provided.

### BRIEF DESCRIPTION OF THE DRAWINGS

FIG. 1A is a sectional view of a photoelectric conversion semiconductor layer according to a preferred embodiment of the present invention.

FIG. 1B is a sectional view of a photoelectric conversion semiconductor layer according to another preferred embodiment of the present invention.

FIG. 2 illustrates a single grating structure and a double grating structure.

FIG. 3 illustrates the relationship between the lattice constant and band gap of I-III-VI compound semiconductors.

FIG. 4A is a schematic sectional view of a photoelectric conversion device according to an embodiment of the present invention taken along a lateral direction.

FIG. 4B is a schematic sectional view of a photoelectric conversion device according to an embodiment of the present invention taken along a longitudinal direction.

FIG. 5 is a schematic sectional view of an anodized substrate illustrating the structure thereof.

FIG. 6 is a perspective view of an anodized substrate illustrating a manufacturing method thereof.

FIG. 7 is a TEM surface photograph of a plate-like particle.

### BEST MODE FOR CARRYING OUT THE INVENTION

### [Photoelectric Conversion Semiconductor Layer]

A photoelectric conversion semiconductor layer of the present invention is a particle layer in which a plurality of plate-like particles is disposed only in a plane direction or a sintered body thereof, or a particle layer in which a plurality of plate-like particles is disposed in a plane direction and a thickness direction or a sintered body thereof.

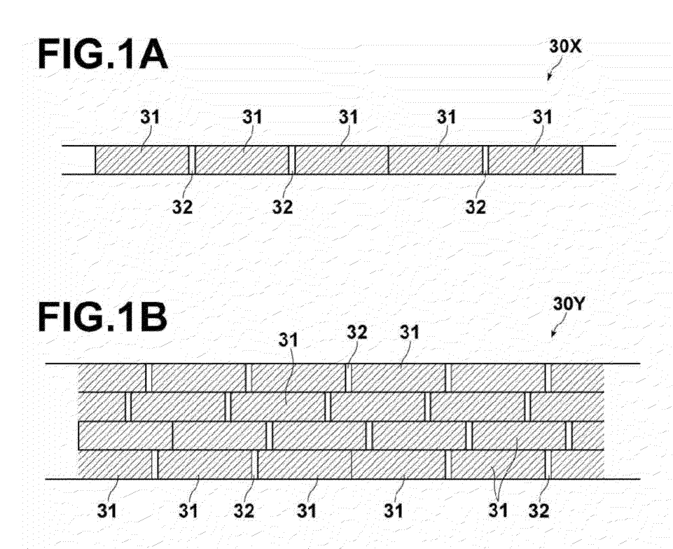

Photoelectric conversion semiconductor layers according to preferred embodiments of the present invention will now be described with reference to the accompanying drawings. FIGS. 1A and 1B are schematic cross-sectional views of photoelectric conversion semiconductor layers taken along a thickness direction. Note that each component in the drawing is not drawn to scale.

Photoelectric conversion semiconductor layer 30X shown in FIG. 1A is a photoelectric conversion semiconductor layer formed of a particle layer having a single layer structure in which plurality of plate-like particles 31 is disposed only in a plane direction. While photoelectric conversion semiconductor layer 30Y shown in FIG. 1B is a photoelectric conversion semiconductor layer formed of a particle layer having a laminated structure in which plurality of plate-like particles 31 is disposed in a plane direction and a thickness direction. FIG. 1B shows a 4-layer structure as an example. In photoelectric conversion semiconductor layer 30X or 30Y, gap 32 may or may not be present between adjacent plate-like particles 31.

The photoelectric conversion semiconductor layer may be a sintered body of the particle layer shown in FIG. 1A or a sintered body of the particle layer shown in FIG. 1B.

Preferably, the photoelectric conversion semiconductor layer of the present invention is manufactured without heat-treated at a temperature higher than 250° C. Although, it has been described that sintered bodies of the particle layers may be used as the photoelectric conversion semiconductor layer, but the particle layers not subjected to sintering are more preferable. That is, it is more preferable that the photoelectric conversion semiconductor layer of the present invention is formed of a particle layer in which a plurality of particles is disposed only in a plane direction or a particle layer in which a plurality of particles is disposed in a plane direction and a thickness direction.

There is not any specific restriction on the surface shapes of the plurality of plate-like particles, and one of a substantially hexagonal shape, a triangular shape, a circular shape, and a rectangular shape is preferably used. The inventor of the present invention has succeeded in synthesizing a plate-like particle having a substantially hexagonal shape, a triangular shape, a circular shape, or a rectangular shape when “Examples” were produced which will be described later.

The term “plate-like particle” as used herein refers to a particle having a pair of opposite main surfaces. Here, the “main surface” refers to a surface having a largest area of all of the outer surfaces of the particle. The term “surface shape of the plate-like particle” as used herein refers to the shape of the main surface. The term “a substantially hexagonal shape (a substantially triangular shape, or a substantially rectangular shape)” as used herein refers to a hexagonal shape (a triangular shape, or a rectangular shape) and the hexagonal shape (triangular shape, or rectangular shape) with a rounded corner. The term “a substantially circular shape” as used herein refers to a circular shape and a round shape similar to the circular shape.

There is not any specific restriction on the average thickness of the plate-like particles. A smaller number of particle layers are more preferable and a single layer structure is particularly preferable because of reduced grain boundaries between the electrodes. Thus, it is particularly preferable that the average thickness of the plate-like particles is set to the thickness of the photoelectric conversion semiconductor layer and the photoelectric conversion semiconductor layer is formed of the particle layer having a single layer structure. In this case, the upper and lower electrodes can be connected by one plate-like particle and the grain boundary can be eliminated between the upper and lower electrodes, whereby a high photoelectric conversion efficiency which is comparable to that of a photoelectric conversion layer formed by vacuum film forming may be achieved.

Preferably, the average thickness of a plurality of plate-like particles constituting the photoelectric conversion semiconductor layer of the present invention is in the range from 0.05 to 3.0 μm, more preferably in the range from 0.1 to 2.5 μm, and particularly preferable in the range from 0.3 to 2.0 μm when the photoelectric conversion efficiency and ease of manufacture of the particles are taken into account. The inventor of the present invention has realized a photoelectric conversion efficiency of 14% with a photoelectric conversion layer formed of a particle layer having a single layer structure using plate-like particles with an average thickness of 1.5 μm in Example 1 to be described later. Further, the inventor of the present invention has realized a photoelectric conversion efficiency of 12% with a photoelectric conversion layer formed of a particle layer having a four layer structure using plate-like particles with an average thickness of 0.4 μm in Example 2 to be described later.

There is not any specific restriction on the aspect ratio of plate-like particles (cross-sectional aspect ratio in thickness direction of photoelectric conversion layer) constituting the photoelectric conversion semiconductor layer of the present invention. For a nearly cubic less anisotropic shape, it is difficult to dispose a plurality of plate-like particles such that the main surfaces of the particles are arranged parallel to the surface of the substrate. A higher aspect ratio shape is preferable because it allows easy disposition of a plurality of particles with the main surfaces being arranged parallel to the surface of the substrate. Preferably, the aspect ratio of the plurality of plate-like particles is 3 to 50 when the orientation of the particles, i.e., ease of manufacture of the photoelectric conversion semiconductor layer is taken into account.

There is not any specific restriction on the average equivalent circle diameter of plate-like particles constituting the photoelectric conversion semiconductor layer of the present invention. A larger diameter is more preferable because a larger value provides a larger light receiving area. Preferably, the average equivalent circle diameter of a plurality of plate-like particles is, for example, in the range from 0.1 to 100 μm when the photoelectric conversion efficiency and ease of manufacture of the photoelectric conversion semiconductor layer.

There is not any specific restriction on the coefficient of variation of equivalent circle diameter of a plurality of plate-like particles, and it is preferable that the coefficient of variation is monodisperse or close to it in order to manufacture the photoelectric conversion semiconductor layer with a stable quality. More specifically, it is preferable that the coefficient of variation of equivalent circle diameter is less than 40% and more preferably less than 30%.

Here, the “average equivalent circle diameter of a plurality of plate-like particles” is evaluated with a transmission electron microscope (TEM). For example, Scanning Transmission Electron Microscope HD-2700 (Hitachi) or the like may be used for the evaluation. The “average equivalent circle diameter” is calculated by obtaining diameters of circles circumscribing approximately 300 plate-like particles and averaging the diameters. The “coefficient of variation of equivalent circle diameter (dispersion)” is statistically obtained from the particle diameter evaluation using the TEM.

The “thickness of each plate-like particle” is calculated in the following manner. That is, multiple plate-like particles are distributed on a mesh and carbon or the like is deposited at a given angle from above to implement shadowing, which is then photographed by a scanning electron microscope (SEM) or the like. Thereafter, the thickness of each plate-like particle is calculated based on the length of the shadow obtained from the image and the deposition angle. The average value of the thickness is obtained by averaging the thicknesses of about 300 plate-like particles as in the equivalent circle diameter.

The “aspect ratio of each plate-like particle” is obtained from the equivalent circle diameter and thickness obtained in the manner as described above.

Preferably, the major component of the photoelectric conversion semiconductor layer is at least one type of compound semiconductor having a chalcopyrite structure. Preferably, the major component of the photoelectric conversion semiconductor layer is at least one type of compound semiconductor formed of a group Ib element, a group IIIb element, and a group VIb element.

As having a high light absorption rate and providing high photoelectric conversion efficiency, it is preferable that the major component of the photoelectric conversion layer is at least one type of compound semiconductor (S) formed of at least one type of group Ib element selected from the group consisting of Cu and Ag, at least one type of group IIIb element selected from the group consisting of Al, Ga, and In, and at least one type of group VIb element selected from the group consisting of S, Se, and Te.

Element group representation herein is based on the short period periodic table. A compound semiconductor formed of a group Ib element, a group IIIb element, and a group VI element is sometimes represented herein as “group I-III-VI semiconductor” for short. Each of the group Ib element, group IIIb element, and group VI element, which are constituent elements of group I-III-VI semiconductor, may be one type or two or more types of elements.

Compound semiconductors (S) include CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS) Cu(In₁₋ₓAlₓ)Se₂, Cu(In₁₋ₓGaₓ)(S, Se)₂, Ag(In₁₋ₓGaₓ)Se₂, Ag(In₁₋ₓGaₓ)(S, Se)₂, and the like.

It is particularly preferable that the photoelectric conversion semiconductor layer includes CuInS₂, CuInSe₂ (CIS), or these compounds solidified with Ga, i . e, Cu(In,Ga)S₂, Cu(In,Ga)Se₂ or compounds of these selenium sulfides. The photoelectric conversion semiconductor layer may include one or more types of these. CIS, CIGS, and the like are reported to have a high light absorption rate and high energy conversion efficiency. Further, they are excellent in the durability with less deterioration in the conversion efficiency due to light exposure and the like.

If the photoelectric conversion semiconductor layer is a CIGS layer, there is not any specific restriction on the Ga concentration and Cu concentration in the layer. Preferably, a molar ratio of Ga content with respect to the total content of group III elements in the layer is in the range from 0.05 to 0.6, more preferably in the range from 0.2 to 0.5. Preferably, a molar ratio of Cu content with respect to the total content of group III elements in the layer is in the range from 0.70 to 1.0, more preferably in the range from 0.8 to 0.98.

The photoelectric conversion semiconductor layer of the present invention includes an impurity for obtaining an intended semiconductor conductivity type. The impurity may be included in the photoelectric conversion semiconductor layer by diffusing from an adjacent layer and/or active doping.

The photoelectric conversion semiconductor layer of the present invention may include one or more types of semiconductors other than the group I-III-VI semiconductor. Semiconductors other than the group I-III-VI semiconductor may include but not limited to a semiconductor of group IVb element, such as Si (group IV semiconductor), a semiconductor of group IIIb element and group Vb element such as GaAs (group III-V semiconductor), and a semiconductor of group IIb element and group VIb element, such as CdTe (group II-VI semiconductor).

The photoelectric conversion semiconductor layer of the present invention may include any arbitrary component other than semiconductors and an impurity for causing the semiconductors to become an intended conductivity type within a limit that does not affect the properties.

The photoelectric conversion semiconductor layer of the present invention may be formed of one type of plate-like particles having the same composition or a plurality of types of plate-like particles having different compositions.

The photoelectric conversion semiconductor layer may have a concentration distribution of constituent elements of group I-III-VI semiconductors and/or impurities, and may have a plurality of layer regions of different semiconductivities, such as n-type, p-type, i-type, and the like.

In the embodiment shown in FIG. 1B, a plurality of types of particles having different band gaps may be used as plurality of plate-like particles 31 to produce a potential (band gap) distribution in a thickness direction. Such structure allows a higher design value for the photoelectric conversion efficiency. There is not any specific restriction on the potential (band gap) slope structure in the thickness direction and a single grating structure, a double grating structure, or the like is preferably used.

In any grating structure, it is said that carriers induced by light are more likely to reach the electrode due to acceleration by an electric field inside of the band structure generated by the gradient thereof, whereby the probability of recombination in the recombination center is reduced and the photoelectric conversion efficiency is enhanced (International Patent Publication No. WO2004/090995 and the like). For details of the single grating structure and double grating structure, refer to “A new approach to high-efficiency solar cells by band gap grading in Cu(In,Ga)Se₂ chalcopyrite semiconductors”, T. Dullweber et al., Solar Energy Materials and Solar Cells, Vol. 67, pp. 145-150, 2001 and the like.

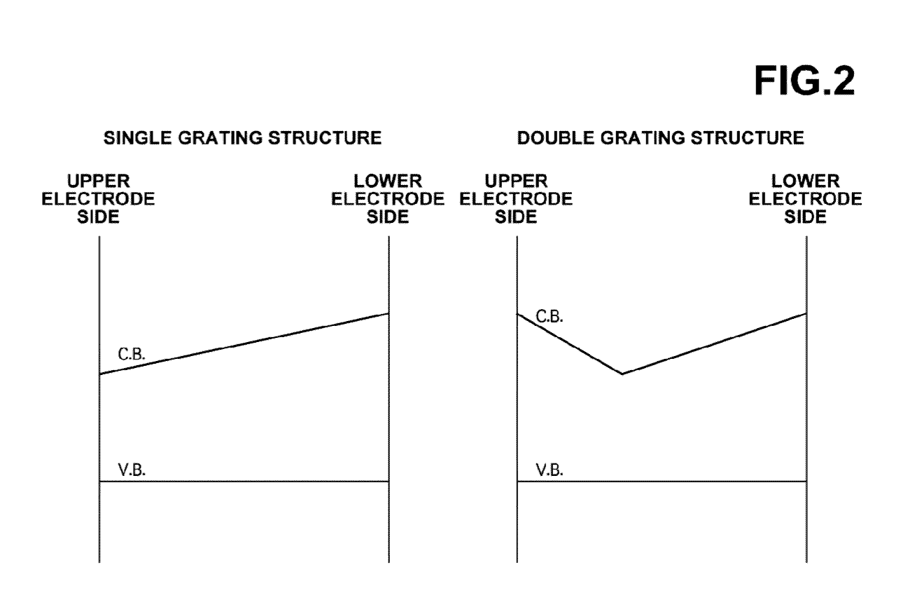

FIG. 2 schematically illustrates a conduction band (C.B.) and a valence band (V.B.) in a thickness direction in each of the single and double grating structures. In the single grating structure, C.B. gradually decreases from the lower electrode side toward the upper electrode side. In the double grating structure, C.B. gradually decreases from the lower electrode side toward the upper electrode side but gradually increases from a certain position. Whereas the graph representing the relationship between the position in the thickness direction and potential has one gradient in the single grating structure, the graph representing the relationship between the position in the thickness direction and potential has two gradients in the double grating structure and the two gradients have different (positive and negative) signs.

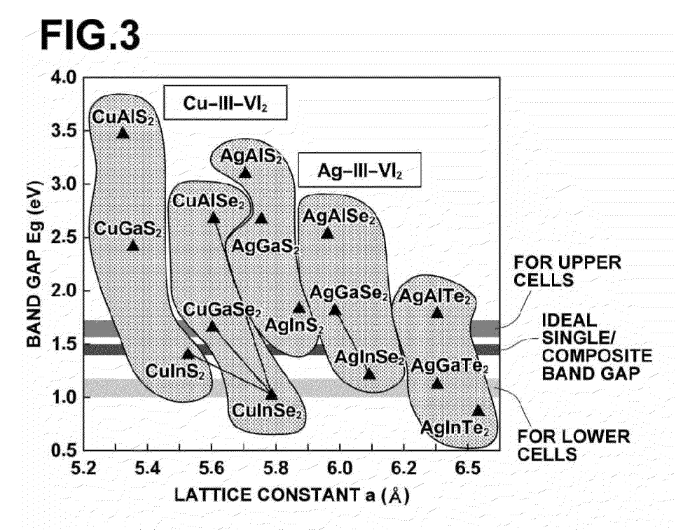

FIG. 3 illustrates the relationship between the lattice constant and band gap of major I-III-VI compound semiconductors. FIG. 3 shows that various band gaps may be obtained by changing the composition ratio. That is, by using a plurality of types of particles, in which at least one type of element among the group Ib element, group IIIb element, and group VIb element has different concentrations, as plurality of plate-like particles 31 to change the concentration of the element in the thickness direction, the potential in the thickness direction may be changed.

For the compound semiconductors (S) described above, the element for changing the concentration in the thickness direction is at least one type of element selected from the group consisting of Cu, Ag, Al, Ga, In, S, Se, and Te, and more preferably at least one type of element selected from the group consisting of Ag, Ga, Al, and S.

For example, composition gradation structures in which Ga concentration in Cu(In,Ga)Se₂ (CIGS) in the thickness direction is changed, Al concentration in Cu(In,Al)Se₂ in the thickness direction is changed, Ag concentration in (Cu,Ag)(In,Ga)Se₂ in the thickness direction is changed, S concentration in Cu (In,Ga)(S,Se)₂ in the thickness direction is changed may be cited. In the case of CIGS, for example, the potential may be changed in the range from 1.04 to 1.68 eV by changing the Ga concentration. When providing a gradient in the Ga concentration in CIGS, there is not any specific restriction on the minimum Ga concentration which, when the maximum Ga concentration of the particles is assumed to be 1, is preferable in the range from 0.2 to 0.9, more preferably in the range from 0.3 to 0.8, and particularly preferable in the range from 0.4 to 0.6.

The distribution of the composition may be evaluated by a measuring equipment of FE-TEM, which is capable of narrowing the electron beam, with an EDAX attached thereto. The composition distribution may also be measured from the half bandwidth of emission spectrum using the method disclosed in International Patent Publication No. WO2006/009124. Generally, different compositions of the particles result in different band gaps, and thus the emission wavelengths due to recombination of the excited electrons are also different. Consequently, a broad composition distribution of the particles results in a broad emission spectrum.

The correlation between the half bandwidth of emission spectrum and composition distribution of particles may be confirmed by measuring the composition of the particles with the EDAX attached to the FE-TEM and taking the correlation with the emission spectrum. There is not any specific restriction on the wavelength of the excitation light used for measuring the emission spectrum, which is preferably in the range from near ultraviolet region to visible light region, more preferably in the range from 150 to 800 nm, and particularly preferably in the range from 400 to 700 nm.

For example, in the actual measurement results carried out by the inventor of the present invention, in which the average Ga element ratio with respect to the total element ratio of In and Ga was set to 0.5 in a CIGS and excited with 550 nm, the half bandwidth of emission spectrum was 450 nm when the coefficient of variation was 60% and 200 nm when the coefficient of variation was 30%. In this way, the half bandwidth of the emission spectrum reflects the composition distribution of the particles.

There is not any specific restriction on the half bandwidth of emission spectrum and, for example in the case of a CIGS, is preferable to be in the range from 5 to 450 run. The lower limit of 5 nm is due to thermal fluctuation and any half bandwidth lower than that is theoretically impossible.

### (Photoelectric Conversion Semiconductor Layer Manufacturing Method)

A first photoelectric conversion semiconductor layer manufacturing method of the present invention is a method of manufacturing the photoelectric conversion semiconductor layer described above and includes a step of applying a coating material, which includes a plurality of plate-like particles described above or the plurality of plate-like particles and a dispersion medium, on a substrate.

A second photoelectric conversion semiconductor layer manufacturing method of the present invention is a method of manufacturing the photoelectric conversion semiconductor layer described above and includes the steps of applying a coating material, which includes a plurality of plate-like particles and a dispersion medium, on a substrate and removing the dispersion medium. Preferably, the step of removing the dispersion medium is a step performed at a temperature not higher than 250° C.

### <Particle Manufacturing Method>

There is not any specific restriction on the method of manufacturing the plate-like particles used in the photoelectric conversion semiconductor layer of the present invention. In the past, a manufacturing method of plate like particles was reported only in Non-patent Document 7. The inventor of the present invention has succeeded in synthesizing plate-like particles by a novel method which is different from the known method described in Non-patent Document 7 (refer to “Examples” described hereinafter).

Metal-chalcogen particles may be manufactured by gas phase methods, liquid phase methods, or other particle forming methods of compound semiconductors. When the avoidance of particle aggregation and mass productivity are taken into account, liquid phase methods are preferable. Liquid phase methods include, for example, polymer existence method, high boiling point solvent method, regular micelle method, and reverse micelle method.

A preferable method of manufacturing metal-chalcogen particles is to cause reaction between the metal and chalcogen, which are in the form of salt or complex, in an alcohol based solvent and/or in an aqueous solution. In this method, the reaction is implemented through a metathetical reaction or a reduction reaction.

Plate-like particles having a desired shape and size may be manufactured by adjusting reaction conditions. For example, the inventor of the present invention has found that the surface shapes of the plate-like particles can be changed by changing pH of the reaction solution, whereby plate-like particles having a desired shape may be obtained (refer to “Examples” described hereinafter).

Metal salts or metal complexes include metallic halides, metallic sulfides, metallic nitrates, metallic sulfates, metallic phosphates, metallic complex salts, ammonium complex salts, chloro complex salts, hydroxo complex salts, cyano complex salts, metal alcoholates, metal phenolates, metallic carbonates, metallic carboxylate salts, metallic hydrides, metallic organic compounds, and the like. Chalcogen salts or chalcogen complexes include alkali metal salts and alkali, alkaline earth metal salt, and the like. In addition, thioacetamides, thiols, and the like may be used as the source of the chalcogen.

Alcohol based solvents include methanol, ethanol, propanol, butanol, methoxyethanol, ethoxyethanol, ethoxypropanol, tetrafluoropropanol, and the like, in which ethoxyethanol, ethoxypropanol, or tetrafluoropropanol is preferably used.

There is not any specific restriction on the reducing agent used for reducing the metal compounds and, for example, hydrogen, sodium tetrahydroborate, hydrazine, hydroxylamine, ascorbic acid, dextrin, superhydride (LiB(C₂H₅)₃H), alcohols, and the like may be cited.

When causing the reaction described above, it is preferable to use an adsorption group containing low molecular dispersant. As for the adsorption group containing low molecular dispersant, those soluble in alcohol based solvents or water are used. Preferably, the molecular mass of the low molecular dispersant is not greater than 300, more preferably not greater than 200. As for the adsorption group, —SH, —CN, —NH₂, —SO₂OH, —COOH, and the like are preferably used, but not limited to these. It is also preferable to have a plurality of these groups. As for the dispersant, compounds represented by R—SH, R—NH₂, R—COOH, HS—R′—(SO₃H)ₙ, HS—R′—NH₂, HS—R′—(COOH)ₙ, and the like are preferable.

In the chemical formulae above, R represents an aliphatic group, an aromatic group, or a heterocyclic group (group in which one hydrogen atom is removed from a heterocyclic ring), R′ represents a group in which a hydrogen atom of R is further substituted. As for R′, alkylene groups, arylene groups, and heterocyclic ring linking groups (group in which two hydrogen atoms are removed from a heterocyclic ring) are preferable. As for the aromatic group, substituted or non-substituted phenyl groups and naphthyl groups are preferable. As for the heterocyclic ring of the heterocyclic group or heterocyclic ring linking group, azoles, diazoles, triazoles, tetrazoles, and the like are preferable. A preferable value of “n” is from 1 to 3. Examples of adsorption group containing low molecular dispersants include mercaptopropanesulfonate, mercaptosuccinic acid, octanethiol, dodecanethiol, thiophenol, thiocresol, mercaptobenzimidazole, mercaptobenzothiazole, 5-amino-2-mercapto thiadiazole, 2-mercapto-3-phenylimidazole, 1-dithiazolyl butyl carboxylic acid, and the like. Preferably, the additive amount of the dispersant is 0.5 to 5 times by mol of the particles produced and more preferably 1 to 3 times by mol.

Preferably, the reaction temperature is in the range from 0 to 200° C. and more preferably in the range from 0 to 100° C. The relative proportion in the intended composition ratio is used for the molar ratio of the salt or complex salt to be added. The adsorption group containing low molecular dispersant may be added to the solution before, during, or after reaction.

The reaction may be implemented in an agitated reaction vessel, and a magnetic driven sealed type small space agitator may be used. As for the magnetic driven sealed type small space agitator, device (A) disclosed in Japanese Unexamined Patent Publication No. 10(1999)-043570 may be cited as an example. It is preferable to use an agitator having a greater shearing force is used after using the magnetic driven sealed type small space agitator. The agitator having a greater shearing force is an agitator having basically turbine or paddle type agitation blades with a sharp cutting edge located at the tip of each blade or at a position where each blade meets. Specific examples include Dissolver (Nihon-tokusyukikai), Omni Mixer (yamato scientific co. ltd.), Homogenizer (STM), and the like.

Since particles are produced from a reaction solution, unwanted substances such as a by-product, an excessive amount of dispersant, and the like may be removed by a well known method, such as decantation, centrifugation, ultrafiltration (UF). As for the wash solution, alcohol, water, or a mixed solution of alcohol and water is used, and washing is performed in such a manner as to avoid aggregation and dryness.

With respect to the method of forming metal-chalcogen particles, a metal salt or comoplex and a chalcogen salt or comoplex may be included in a reverse micelle and mixed, thereby causing a reaction between them. Further, a reducing agent may be included in the reverse micelle while the reaction is taking place. More specifically, a method described, for example, in Japanese Unexamined Patent Publication No. 2003-239006, Japanese Unexamined Patent Publication No. 2004-052042, or the like may be cited as a reference. Further, a particle forming method through a molecular cluster described in PCT Japanese Publication No. 2007-537866 may also be used.

Still further, particle forming methods described in the following documents may also be used: PCT Japanese Publication No. 2002-501003; U.S. Patent Application Publication No. 20050183767; International Patent Publication No. WO2006/009124; “Synthesis of Chalcopyrite Nanoparticles via Thermal Decomposition of Metal-Thiolate”, T. Kino et al., Materials Transaction, Vol. 49, No. 3, pp. 435-438, 2008, “Cu(In,Ga)(S,Se)₂ solar cells and modules by electrodeposition”, S. Taunier et al., Thin Solid Films, Vols. 480-481, pp. 526-531, 2005; “Synthesis of CuInGaSe₂ nanoparticles by solvothermal route”, Y. G. Chun et al., Thin Solid Films, Vols. 480-481, pp. 46-49, 2005; “Nucleation and growth of Cu(In,Ga)Se₂ nano particles in low temperature colloidal process”, S. Ahn et al., Thin Solid Films, Vol. 515, Issues 7-8, pp. 4036-4040, 2007; “Cu—In—Ga—Se nanoparticle colloids as spray deposition precursors for Cu(In,Ga)Seₑ solar cell materials”, D. L. Schulz et al., Journal of Electronic Materials, Vol. 27, No. 5, pp. 433-437, 2007; and the like.

### <Coating Step>

There is not any specific restriction on the method of coating a coating material which includes a plurality of plate-like particles or a plurality of plate-like particles and a dispersion medium on a substrate. Preferably, the substrate is sufficiently dried prior to the coating step.

As for the coating method, web coating, spray coating, spin coating, doctor blade coating, screen printing, ink-jetting, and the like may be used. The web coating, screen printing, and ink-jetting are particularly preferable because they allow roll-to-roll manufacturing on a flexible substrate.

The dispersion medium may be used as required. Liquid dispersion media, such as water, organic solvent, and the like are preferably used. As for the organic solvent, polar solvents are preferable, and alcohol based solvents are more preferable. The alcohol based solvents include methanol, ethanol, propanol, butanol, methoxyethanol, ethoxyethanol, ethoxypropanol, tetrafluoropropanol, and the like, and ethoxyethanol, ethoxypropanol, or tetrafluoropropanol is preferably used. As for the solution properties of the coating material, including the viscosity, surface tension, and the like, are adjusted in preferable ranges using a dispersion medium described above according to the coating method employed. As for the dispersion medium, a solid dispersion medium may also be used. Such solid dispersion media include, for example, an absorption group containing low molecular dispersant and the like.

In the present invention, plate-like particles are used for forming a photoelectric conversion layer, thus when the coating material is coated, the particles are spontaneously disposed on the substrate such that the main surfaces thereof are arranged parallel to the surface of the substrate, thereby forming a particle layer. When stacking particles in a thickness direction, the plurality of particle layers may be formed one by one or simultaneously. Where the composition in the thickness direction is changed, first a single particle layer may be formed using particles having the same composition and then the layer forming may be repeated by changing the composition or a plurality of particle layers having different compositions in the thickness direction may be formed at a time by simultaneously supplying a plurality types of particles having different compositions.

### <Dispersion Medium Removal Step>

Where a dispersion medium is used, a dispersion medium removal step may be performed, as required, after the coating step described above. Preferably, the dispersion medium removal step is a step performed at a temperature not higher than 250° C.

Liquid dispersion media such as water, organic solvent, and the like may be removed by normal pressure heat drying, reduced pressure drying, reduced pressure heat drying, and the like. Liquid dispersion media such as water, organic solvent, and the like can be sufficiently removed at a temperature not higher than 250° C. Solid dispersion media can be removed by solvent melting, normal pressure heating, or the like. Most organic substances are decomposed at a temperature not higher than 250° C., so that solid dispersion media can be sufficiently removed at a temperature not higher than 250° C.

In this way, the photoelectric conversion semiconductor layer of the present invention formed of a particle layer in which a plurality of plate-like particles is disposed only in a plane direction or a particle layer in which a plurality of plate-like particles is disposed in a plane direction and a thickness direction.

The photoelectric conversion semiconductor layer of the present invention may be manufactured by non-vacuum processing which requires less cost than vacuum processing. The photoelectric conversion semiconductor layer of the present invention does not essentially requires sintering at a temperature exceeding 250° C. and can be made by the processing at a temperature not higher than 250° C. This eliminates the need for high temperature processing equipment and the photoelectric conversion semiconductor layer may be manufactured at a low cost.

It has been described, under the “Background Art”, that Non-patent Documents 4 to 6 propose a method in which spherical CIGS particles are coated on a substrate and thereafter a high temperature heat treatment process is not implemented. The CIGS layer described in these literatures is a particle layer formed of a plurality of spherical particles, having a small contact area of the CIGS layer with an electrode, so that it is difficult to realize a photoelectric conversion efficiency which is comparable to that of a CIGS layer formed by vacuum film forming. For example, Non-patent Document 6 reports a conversion efficiency of 5.7% which is less than a half of that of the photoelectric conversion efficiency of the CIGS layer formed by vacuum film forming, proving that it is an unpractical level.

In the present invention, plate-like particles are used. This may provide a larger contact area between the photoelectric conversion layer and an electrode, resulting in a smaller contact resistance, as well as larger contact area between the particles and larger light receiving area for each particle. Consequently, a photoelectric conversion efficiency which is higher than those described in the literatures in Non-patent Documents 4 to 6 may be realized even if a high temperature heat treatment process is not implemented. The inventor of the present invention has realized photoelectric conversion efficiencies of 12 to 14% in Examples 1 to 4 to be described later.

In the present invention, it is preferable not to implement a high temperature heat treatment process, but sintering at a temperature exceeding 250° C. may be performed. In this case, a photoelectric conversion semiconductor layer of the present invention formed of a sintered particle layer in which a plurality of plate-like particles is disposed only in a plane direction or a photoelectric conversion semiconductor layer of the present invention formed of a sintered particle layer in which a plurality of plate-like particles is disposed in a plane direction and a thickness direction may be obtained.

As described under the “Background Art”, the conventional CIGS manufacturing methods generally perform sintering at a temperature around 500° C., while the present invention may provide a high photoelectric conversion efficiency even without performing sintering, thus if sintering should be implemented, a minimum heat treatment is enough.

When a particle layer in which a plurality of plate-like particles is disposed only in a plane direction or a particle layer in which a plurality of plate-like particles is disposed in a plane direction and a thickness direction is sintered, fusion occurs between adjacent plate-like particles. In this case, the fused surfaces of the plate-like particles remain as crystal grain boundaries to a degree that makes the shapes of plate-like particles recognizable even after the sintering.

Where sintering is performed, the absolute number of particles in the photoelectric conversion layer is small and the bonding area between adjacent particles is also small, so that the number of crystal grain boundaries is relatively small, and the bonding area remaining as a grain boundary is smooth and large in comparison with the case in which spherical particles are used, whereby a high photoelectric conversion efficiency is obtained.

Sintering may evaporate such elements as Se, S, and the like. Therefore, where a photoelectric conversion layer containing such an element is formed, it is preferable to add a compound containing the element when coating plate-like particles or performing the sintering in the presence of the element.

As described above, according to the present invention, a photoelectric conversion semiconductor layer which can be manufactured at a lower cost than that manufactured by a vacuum film forming and has a higher photoelectric conversion efficiency than that described in Non-patent Documents 4 to 6 and a method of manufacturing the layer may be provided. According to the present invention, a photoelectric conversion semiconductor layer which can be manufactured at a lower cost than that manufactured by vacuum film forming without requiring, as essential processing, high temperature processing exceeding 250° C. and has a higher photoelectric conversion efficiency than that described in Non-patent Document 4 to 6 and a method of manufacturing the layer may be provided.

### [Photoelectric Conversion Device]

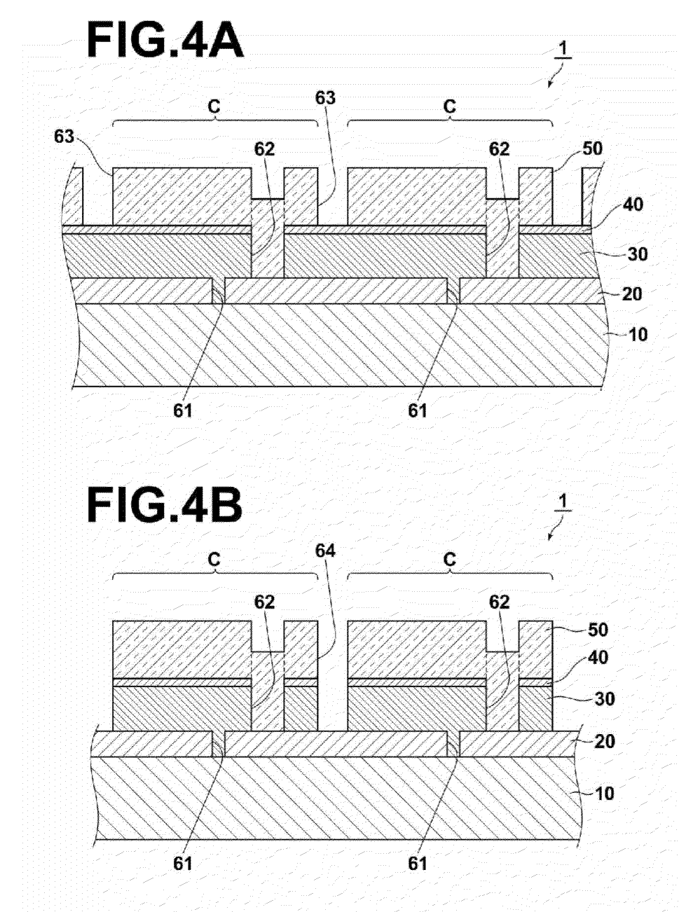

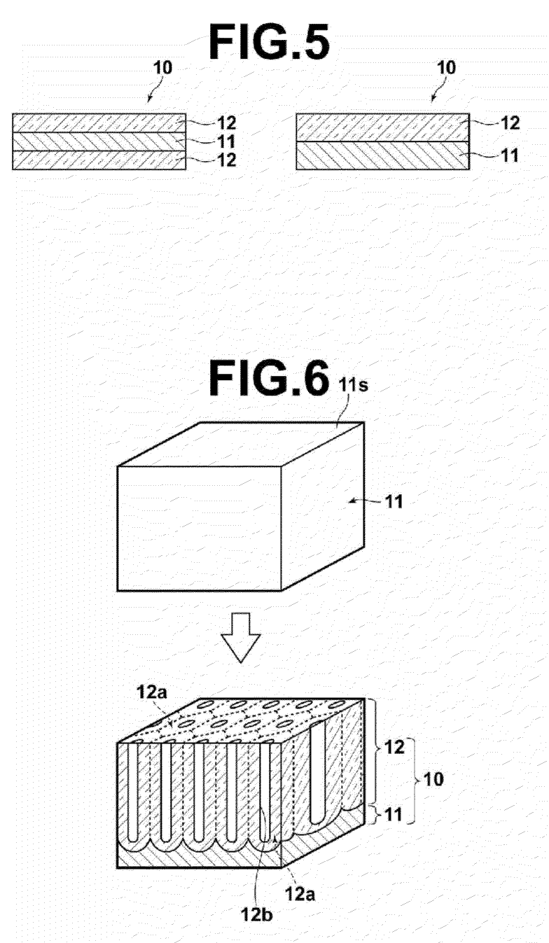

A structure of a photoelectric conversion device according to an embodiment of the present invention will be described with reference to the accompanying drawings. FIG. 4A is a schematic sectional view of the photoelectric conversion device in a lateral direction, and FIG. 4B is a schematic sectional view of the photoelectric conversion device in a longitudinal direction. FIG. 5 is a cross-schematic sectional view of a substrate, illustrating the structure thereof, and FIG. 6 is a perspective view of a substrate, illustrating a manufacturing method thereof. In the drawings, each component is not drawn to scale in order to facilitate visual recognition.

Photoelectric conversion device 1 is a device having substrate 10 on which lower electrode (rear electrode) 20, photoelectric conversion semiconductor layer 30, buffer layer 40, and upper electrode 50 are stacked in this order. Photoelectric conversion semiconductor layer 30 is photoelectric conversion semiconductor layer 30X formed of a particle layer in which a plurality of plate-like particles 31 is disposed only in a plane direction (FIG. 1A) or photoelectric conversion semiconductor layer 30Y formed of a particle layer in which a plurality of plate-like particles 31 is disposed in a plane direction and a thickness direction (FIG. 1B).

Photoelectric conversion device 1 has first separation grooves 61 that run through only lower electrode 20, second separation grooves 62 that run through photoelectric conversion layer 30 and buffer layer 40, and third separation grooves 63 that run through only upper electrode layer 50 in a lateral sectional view and fourth separation grooves 64 that run through photoelectric conversion layer 30, buffer layer 40, and upper electrode layer 50 in a longitudinal sectional view.

The above configuration may provide a structure in which the device is divided into many cells C by first to fourth separation grooves 61 to 64. Further, upper electrode 50 is filled in second separation grooves 62, whereby a structure in which upper electrode 50 of a certain cell C is serially connected to lower electrode 20 of adjacent cell C may be obtained.

### (Substrate)

In the present embodiment, substrate 10 is a substrate obtained by anodizing at least one side of Al based metal base 11. Substrate 10 may be a substrate of metal base 11 having anodized film 12 on each side as illustrated on the left of FIG. 5 or a substrate of metal base 11 having anodized film 12 on either one of the sides as illustrated on the right of FIG. 5. Here, anodized film 12 is an Al₂O₃ based film.

Preferably, substrate 10 is a substrate of metal base 11 having anodized film 12 on each side as illustrated on the left of FIG. 5 in order to prevent warpage of the substrate due to the difference in thermal expansion coefficient between Al and Al₂O₃, and detachment of the film due to the warpage during the device manufacturing process . The anodizing method for both sides may include, for example, a method in which anodization is performed on a side-by-side basis by applying an insulation material and a method in which both sides are anodized at the same time.

When anodized film 12 is formed on each side of substrate 10, it is preferable that two anodized films are formed to have substantially the same film thickness or anodized film 12 on which a photoelectric conversion layer and some other layers are not provided is formed to have a slightly thicker film thickness than that of the anodized film 12 on the other side in consideration of heat stress balance between each side.

Metal base 11 may be Japanese Industrial Standards (JIS) 1000 pure Al or an alloy of Al with another metal element, such as Al—Mn alloy, Al—Mg alloy, Al—Mn—Mg alloy, Al—Zr alloy, Al—Si alloy, Al—Mg—Si, or the like (Aluminum Handbook, Fourth Edition, published by Japan Light Metal Association, 1990). Metal base 11 may include traces of various metal elements, such as Fe, Si, Mn, Cu, Mg, Cr, Zn, Bi, Ni, Ti, and the like.

Anodization may be performed by immersing metal base 11, which is cleaned, smoothed by polishing, and the like as required, as an anode with a cathode in an electrolyte, and applying a voltage between the anode and cathode. As for the cathode, carbon, aluminum, or the like is used. There is not any specific restriction on the electrolyte, and an acid electrolyte containing one type or more types of acids, such as sulfuric acid, phosphoric acid, chromic acid, oxalic acid, sulfamic acid, benzenesulfonic acid, amido-sulfonic acid, and the like, is preferably used.

There is not any specific restriction on the anodizing conditions and dependent on the electrolyte used. As for the anodizing conditions, for example, the following are appropriate: electrolyte concentration of 1 to 80% by mass; solution temperature of 5 to 70° C.; current density in the range from 0.005 to 0.60 A/cm²; voltage of 1 to 200 V; and electrolyzing time of 3 to 500 minutes.

As for the electrolyte, a sulfuric acid, a phosphoric acid, an oxalic acid, or a mixture thereof may preferably be used. When such an electrolyte is used, the following conditions are preferable: electrolyte concentration of 4 to 30% by mass, solution temperature of 10 to 30° C., current density in the range from 0.05 to 0.30 A/cm², and voltage of 30 to 150 V.

As shown in FIG. 6, when Al based metal base 11 is anodized, an oxidization reaction proceeds from surface 11s in a direction substantially perpendicular to surface 11s, and Al₂O₃ based anodized film 12 is formed. Anodized film 12 generated by the anodization has a structure in which multiple fine columnar bodies, each having a substantially regular hexagonal shape in plan view, are tightly arranged. Each fine columnar body 12a has a fine pore 12b, in substantially the center, extending substantially linearly in a depth direction from surface 11s, and the bottom surface of each fine columnar body 12a has a rounded shape. Normally, a barrier layer without any fine pore 12b is formed (generally, with a thickness of 0.01 to 0.4 μm) at a bottom area of fine columnar bodies 12a. Anodized film 12 without any fine pore 12b may also be formed by appropriately arranging the anodizing conditions.

There is not any specific restriction on the diameter of fine pore 12b of anodized film 12. Preferably the diameter of fine pore 12b is 200 nm or less, and more preferably 100 nm or less from the viewpoints of surface smoothness and insulation properties. It is possible to reduce the diameter of fine pore 12b to about 10 nm.

There is not any specific restriction of the pore density of fine pores 12b of anodized film 12. Preferably, the pore density of fine pores 12b is 100 to 10000/μm², and more preferably 100 to 5000/μm², and particularly preferably 100 to 1000/μm² from the viewpoint of insulation properties.

There is not any specific restriction on the surface roughness Ra. From the viewpoint of uniformly forming the upper layer of photoelectric conversion layer 30, high surface smoothness is desirable. Preferably, the surface roughness Ra is 0.3 μm or less, and more preferably 0.1 μm or less.

There is not any specific restriction on the thicknesses of metal base 11 and anodized film 12. Preferably, the thickness of metal base 11 prior to anodization is, for example, 0.05 to 0.6 mm, and more preferably 0.1 to 0.3 mm in consideration of the mechanical strength of substrate 10, and reduction in the thickness and weight. When the insulation properties, mechanical strength, and reduction in the thickness and weight are taken into account, a preferable range of the thickness of anodized film 12 is 0.1 to 100 μm.

Fine pores 12b of anodized film 12 may be sealed by any known sealing method as required. The sealed pores may increase the withstand voltage and insulating property. Further, if the pores are sealed using a material containing an alkali metal, when photoelectric conversion layer 30 of CIGS or the like is annealed, the alkali metal, preferably Na, diffuses in photoelectric conversion layer 30, whereby the crystallization of photoelectric conversion layer 30, and hence photoelectric conversion efficiency, may sometimes be improved.

### (Electrodes, Buffer Layer)

Each of lower electrode 20 and upper electrode 50 is made of a conductive material. Upper electrode 50 on the light input side needs to be transparent. There is not any specific restriction on the major component of lower electrode 20 and Mo, Cr, W, or a combination thereof is preferably used, in which Mo is particularly preferable. There is not any specific restriction on the thickness of lower electrode 20 and a value in the range from 0.3 to 1.0 μm is preferably used. There is not any specific restriction on the major component of upper electrode 50 and ZnO, ITO (indium tin oxide), SnO₂, or a combination thereof is preferably used. There is not any specific restriction on the thickness of upper electrode 50 and a value in the range from 0.6 to 1.0 μm is preferably used. Lower electrode 20 and/or upper electrode 50 may have a single layer structure or a laminated structure, such as a two-layer structure. There is not any specific restriction on the method of forming lower electrode 20 and upper electrode 50, and vapor deposition methods, such as electron beam evaporation and sputtering may be used.

There is not any specific restriction on the major component of buffer layer 40 and CdS, ZnS, ZnO, ZnMgO, ZnS(O,OH), or a combination thereof is preferably used. There is not any specific restriction on the thickness of buffer layer 40 and a value in the range from 0.03 to 0.1 μm is preferably used. A preferable combination of the compositions is, for example, Mo lower electrode/CdS buffer layer/CIGS photoelectric conversion layer/ZnO upper electrode.

There is not any specific restriction on the conductivity type of photoelectric conversion layer 30 to upper electrode 50. Generally, photoelectric conversion layer 30 is a p-layer, buffer layer 40 is an n-layer (n-Cds, or the like), and upper electrode 50 is an n-layer (n-ZnO layer, or the like) or has a laminated structure of i-layer and n-layer (i-ZnO layer and n-ZnO, or the like). It is believed that such conductivity types form a p-n junction or a p-i-n junction between photoelectric conversion layer 30 and upper electrode 50. Further, it is thought that provision of CdS buffer layer 40 on photoelectric conversion layer 30 results in an n-layer to be formed in a surface layer of photoelectric conversion layer 30 by Cd diffusion, whereby a p-n junction is formed inside of photoelectric conversion layer 30. It is also conceivable that an i-layer may be provided below the n-layer inside of photoelectric conversion layer 30 to form a p-i-n junction inside of photoelectric conversion layer 30.

### (Other Structures)

It is reported that, in a photoelectric conversion device using a soda lime glass substrate, an alkali metal element (Na element) in the substrate is diffused into the CIGS film, thereby improving energy conversion efficiency. In the present embodiment, it is also preferable to diffuse an alkali metal into the photoelectric conversion layer of CIGS and the like.

As for the alkali metal diffusion method, a method in which a layer including an alkali metal element is formed on a Mo lower electrode by deposition or sputtering as described, for example, in Japanese Unexamined Patent Publication No. 8 (1996) -222750, a method in which an alkali layer of Na₂S or the like is formed on a Mo lower electrode by soaking process as described, for example, in International Patent Publication No. WO03/069684, a method in which a precursor of In, Cu, and Ga metal elements is formed on a Mo lower electrode and then, for example, an aqueous solution including sodium molybdate is deposited on the precursor, or the like may be cited. A sodium silicate layer may be formed on an insulating substrate for supplying alkali metal elements. A polyacid layer, such as sodium polymolybdate, sodium polytungstate, or the like, may be formed on the upper side or lower side of the Mo electrode for supplying alkali metal elements. Lower electrode 20 may be structured such that a layer of one or more types of alkali metal compounds, such as Na₂S, Na₂Se, NaCl, NaF, and sodium molybdate salt, is formed inside thereof.

Photoelectric conversion device 1 may have any other layer as required in addition to those described above. For example, a contact layer (buffer layer) for enhancing the adhesion of layers may be provided, as required, between substrate 10 and lower electrode 20, and/or between lower electrode 20 and photoelectric conversion layer 30. Further, an alkali barrier layer for preventing diffusion of alkali ions may be provided, as required, between substrate 10 and lower electrode 20. For details of the alkali barrier layer, refer to Japanese Unexamined Patent Publication No. 8 (1996)-222750.

Photoelectric conversion device 1 of the present embodiment is structured in the manner as described above. The photoelectric conversion device 1 of the present embodiment includes photoelectric conversion semiconductor layer 30, so that it is a device that can be manufactured at a low cost and has a higher photoelectric conversion efficiency than that described in Non-patent documents 4 to 6.

Photoelectric conversion device 1 may be turned into a solar cell by attaching, as required, a cover glass, a protection film, and the like.

### (Design Changes)

The present invention is not limited to the embodiment described above, and design changes may be made as appropriate without departing from the spirit of the present invention.

In the present embodiment, the description has been made of a case in which anodized substrate 10 is used. But, any known substrate including, for example, glass substrates, metal substrates, such as stainless, with an insulation film formed thereon, substrates of resins, such as polyimide, may also be used. The photoelectric conversion device of the present invention can be manufactured by non-vacuum processing and a high temperature heat treatment process is not essential, so that the device can be manufactured quickly through a continuous conveyance system (roll-to-roll process). Accordingly, the use of a flexible substrate, such as an anodized substrate, a metal substrate with an insulation film formed thereon, or a resin substrate is preferable. The present invention does not require a high temperature process so that an inexpensive and flexible resin substrate may also be used.

In order to prevent warpage of the substrate due to thermal stress, it is preferable that the difference in thermal expansion coefficient between the substrate and each layer formed thereon is small. Among the different types of substrates described above, the anodized substrate is particularly preferable from the viewpoint of difference in thermal expansion coefficient with the photoelectric conversion layer or lower electrode (rear electrode), cost, and characteristics required of solar cells or from the viewpoint of easy formation of an insulation film even on a large substrate without any pinhole.

### EXAMPLES

Examples of the present invention and comparable examples will now be described.

### [Plate-Like Particle Synthesis 1 (Plate-Like Particles P1)]

The inventor of the present invention has succeeded in synthesizing plate-like particles by a novel method which is different from the known method described in Non-patent Document 7. Solutions A and B described below were mixed together with a volume ratio of 1:2 at room temperature (about 25° C.) and the mixed solution was agitated at 60° C. for 20 minutes to cause a reaction, whereby CuInS₂ plate-like particles P1 were synthesized. After the reaction was completed, obtained plate-like particles P1 were isolated by a centrifugal separator.
Solution A: solution prepared by adding hydrazine (0.77M) and 2,2′2″-nitrilotriethanol (1.6M) to aqueous solution of copper sulfate (0.1M) and indium sulfate (0.15M), (pH=8.0)
Solution B: aqueous solution of sodium sulfide (0.9M), (pH=12.0) The pH of each solution was adjusted with sodium hydroxide.

TEM observation of the obtained plate-like particles showed that the surface shapes of the particles were substantially hexagonal. The average thickness of the particles was 1.5 μm, average equivalent circle diameter was 10.2 μm, coefficient of variation of the average equivalent circle diameter was 32%, and aspect ratio was 6.8.

### [Plate-like Particle Synthesis 2 (Plate-like Particles P2)]

CuInS₂ plate-like particles P2 were synthesized in the same manner as described above except that the reaction took place at room temperature. TEM observation of the obtained plate-like particles showed that the surface shapes of the particles were substantially hexagonal. The average thickness of the particles was 0.4 μm, average equivalent circle diameter was 2.4 μm, coefficient of variation of the average equivalent circle diameter was 35%, and aspect ratio was 6.0.

### [Plate-Like Particle Synthesis 3]

The inventor of the present invention has found that the surface shapes of the plate-like particles can be changed by changing the pH of solutions A and B. For example, when the pH was adjusted to 12.0 as in the above, the relationship between the pH of solution A and particle shapes was roughly as follows.

pH of solution A≧12: a spherical shape (not fixed)

pH of solution A=9 to 12: a rectangular solid shape

pH of solution A=8 to 9: a hexagonal plate shape

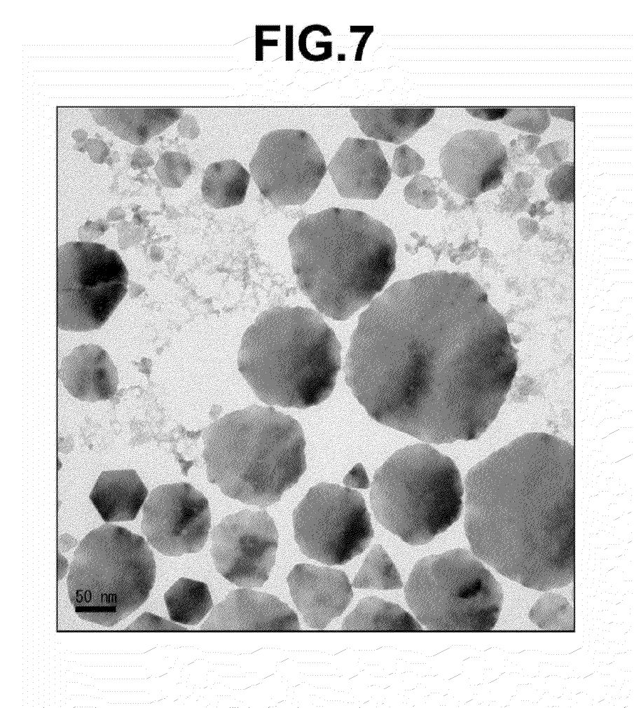

When pH of solution A was 8 and pH of solution B was 11, plate-like particles having various different surface shapes were obtained. A TEM photograph thereof is shown in FIG. 7.

### [Spherical Particle Synthesis 1 (Spherical Particles P3)]

CIGS spherical particles P3 were synthesized by the method described in “Nucleation and growth of Cu(In,Ga)Se₂ nano particles in low temperature colloidal process”, S. Ahn et al., Thin Solid Films, Vol. 515, Issues 7-8, pp. 4036-4040, 2007. The average particle diameter was 0.08 μm and the coefficient of variation of particle diameter was 46%.

### [Spherical Particle Synthesis 2 (Spherical Particles P4)]

CIGS spherical particles P4 were synthesized by the method described in U.S. Pat. No. 6,488,770. The average particle diameter was 1.5 μm and the coefficient of variation of particle diameter was 28%.

### Example 1

A Mo lower electrode was formed on a soda lime glass by RF sputtering. The thickness of the lower electrode was 1.0 μm. Next, plate-like particles P1 described above were dispersed in an aqueous solution containing 0.3M of sodium sulfide at a particle concentration of 30% to prepare a coating material, which was coated on the lower electrode and dried at 200° C. Then, a cyclohexanone solution in which Xeonex (manufactured by Zeon Corporation) was permeated in the coated material and dried. In this way, a CuInS₂ photoelectrical conversion layer in which a plurality of plate-like particles P1 was disposed in a single layer.

Next, a semiconductor film having a laminated structure was formed as a buffer layer. First, a CdS film was deposited by chemical deposition with a thickness of about 50 nm. The chemical deposition was performed by heating an aqueous solution containing nitric acid Cd, thiourea, and ammonium to about 80° C. and immersing the photoelectric conversion layer in the solution. Then, a ZnO film was formed on the Cd film with a thickness of about 80 nm by MOCVD.

Next, a B-doped ZnO film was deposited, as an upper electrode, with a thickness of about 500 nm by MOCVD, and Al was deposited as external extraction electrodes, whereby a photoelectric conversion device of the present invention was obtained. The photoelectric conversion efficiency of the device was evaluated using pseudo sunlight of Air Mass (AM)=1.5, 100 mW/cm² and the result was 14%.

### Example 2

A photoelectric conversion device was obtained in the same manner as in Example 1 except that the particles used were plate-like particles P2, instead of plate-like particles P1, and plate-like particles P2 were disposed in four layers. The photoelectric conversion efficiency of the device measured was 12%.

### Example 3

An aluminum alloy 1050 (Al purity of 99.5%, a thickness of 0.30 mm), used as a base material, was anodized to form an anodized film on each side of the material and the anodized material was subjected to washing and drying, whereby an anodized substrate was obtained. The thickness of the anodized film was 9.0 μm (including a barrier layer thickness of 0.38 μm) with a pore diameter of a fine pore of about 100 nm. The anodization was performed in a 16° C. electrolyte which contains 0.5M of oxalic acid using a DC voltage of 40V. A photoelectric conversion layer of the present invention was obtained in the same manner as in Example 1 except that the anodized substrate was used instead of the soda lime grass substrate. The photoelectric conversion efficiency of the device measured was 13%.

### Example 4

A photoelectric conversion layer of the present invention was obtained in the same manner as in Example 2 except that the process of making the photoelectric conversion layer was changed as follows. A coating material was coated on a substrate having a lower electrode to form four layers of plate-like particles P2as in Example 2. Then, sintering was performed at a temperature of 520° C. for 20 minutes to form a CuInS₂ photoelectric conversion layer. The photoelectric conversion efficiency of the device measured was 14%.

### Comparative Example 1

A photoelectric conversion device for comparison was obtained in the same manner as in Example 1 except that the particles used for forming the photoelectric conversion layer were spherical particles P3 and the process of making the photoelectric conversion layer was changed as follows. After drying, coating material was coated on the lower electrode with a thickness of 0.1 μm. A preheating at a temperature of 200° C. for 10 minutes was repeated 15 times in total, then sintering was performed at a temperature of 520° C. for 20 minutes, and oxygen annealing was performed at a temperature of 180° C. for 10 minutes, whereby a CIGS photoelectric conversion layer was formed. The photoelectric conversion efficiency of the device measured was 11%.

### Comparative Example 2

A photoelectric conversion device was obtained by the method described in Non-patent Document 5 using spherical particles P4 obtained above. The photoelectric conversion efficiency of the device measured was 10%.

Major manufacturing conditions and evaluation results of each example are shown in Table 1.

TABLE 1

| | | | No. of | Heat treatment of P/E Conversion | | | |
|---|---|---|---|---|---|---|---|
| | | Particles | Particle | Layer | | | P/E conversion |
| | Substrate | used | Layers | Pre | Main | Post | Efficiency (%) |
| Eg. 1 | Glass | P-like | One | Not Impled | Not Impled | Not Impled | 14 |
| | | Particles P1 | | | | | |
| | | (1.5 μm thick) | | | | | |
| Eg. 2 | Glass | P-like | Four | Not Impled | Not Impled | Not Impled | 12 |
| | | Particles P2 | | | | | |
| | | (0.4 μm thick) | | | | | |
| Eg. 3 | Anodized | P-like | One | Not Impled | Not Impled | Not Impled | 13 |
| | | Particles P1 | | | | | |
| | | (1.5 μm thick) | | | | | |
| Eg. 4 | Glass | P-like | Four | Not Impled | 520° C. | Not Ipled | 14 |
| | | Particles P2 | | | | | |
| | | (0.4 μm thick) | | | | | |
| C/Eg. 1 | Glass | Spherical | | 250° C. | 520° C. | 180° C. | 11 |
| | | Particles P3 | | 15 times | | O₂ | |
| C/Eg. 2 | Glass | Spherical | | Not Impled | Not Impled | Not Impled | 10 |
| | | Particles P4 | | | | | |

The photoelectric conversion semiconductor layers of the present invention and manufacturing methods thereof are preferably applicable to solar cells, infrared sensors, and the like.

1-18. (canceled)

19. A photoelectric conversion semiconductor layer that generates a current by absorbing light, comprising a particle layer in which a plurality of plate-like particles is disposed only in a plane direction or a sintered body thereof, or a particle layer in which a plurality of plate-like particles is disposed in a plane direction and a thickness direction or a sintered body thereof.

20. The photoelectric conversion semiconductor layer of claim 19, wherein the semiconductor layer comprises the particle layer in which the plurality of plate-like particles is disposed only in the plane direction or the particle layer in which the plurality of plate-like particles is disposed in the plane direction and the thickness direction.

21. The photoelectric conversion semiconductor layer of claim 19, wherein the semiconductor layer includes, as a major component, at least one type of compound semiconductor having a chalcopyrite structure.

22. The photoelectric conversion semiconductor layer of claim 21, wherein the at least one type of compound semiconductor is a semiconductor formed of a group Ib element, a group IIIb element, and a group VIb element.

23. The photoelectric conversion semiconductor layer of claim 22, wherein:
the group Ib element is at least one type of element selected from the group consisting of Cu and Ag;
the group IIIb element is at least one type of element selected from the group consisting of Al, Ga, and In; and
the group VIb element is at least one type of element selected from the group consisting of S, Se, and Te.

24. The photoelectric conversion semiconductor layer of claim 19, wherein a surface shape of the plurality of plate-like particles is at least one of a substantially hexagonal shape, a substantially triangular shape, a substantially circular shape, and a substantially rectangular shape.

25. The photoelectric conversion semiconductor layer of claim 19, wherein an average thickness of the plurality of plate-like particles is in the range from 0.05 to 3.0 μm.

26. The photoelectric conversion semiconductor layer of claim 19, wherein an average equivalent circle diameter of the plurality of plate-like particles is in the range from 0.1 to 100 μm.

27. The photoelectric conversion semiconductor layer of claim 19, wherein a coefficient of variation in the equivalent circle diameter of the plurality of plate-like particles is not greater than 40%.

28. The photoelectric conversion semiconductor layer of claim 19, wherein an aspect ratio of the plurality of plate-like particles is in the range from 3 to 50.

29. A method of manufacturing the photoelectric conversion semiconductor layer of claim 19, the method comprising the step of coating a coating material, which includes the plurality of plate-like particles or the plurality of plate-like particles and a dispersion medium, on a substrate.

30. A method of manufacturing the photoelectric conversion semiconductor layer of claim 19, the method comprising the steps of:
coating a coating material, which includes the plurality of plate-like particles and a dispersion medium, on a substrate; and
removing the dispersion medium.

31. The method of claim 30, wherein the step of removing the dispersion medium is a step performed at a temperature not higher than 250° C.

32. A photoelectric conversion device, comprising the photoelectric conversion semiconductor layer of claim 19 and electrodes for extracting a current generated in the photoelectric conversion semiconductor layer.

33. The photoelectric conversion device of claim 32, wherein the photoelectric conversion semiconductor layer and the electrodes are formed on a flexible substrate.

34. The photoelectric conversion device of claim 33, wherein the flexible substrate is an anodized substrate of Al-based metal base having an anodized film on at least one surface side thereof.

35. A solar cell, comprising the photoelectric conversion device of claim 32.
